(19) United States
(12) Patent Application Publication
(10) Pub. No.: US 2024/0164117 A1
(43) Pub. Date: May 16, 2024

(54) SEMICONDUCTOR DEVICES AND FABRICATION METHODS THEREOF, MEMORY SYSTEMS

(71) Applicant: Yangtze Memory Technologies Co., Ltd., Wuhan (CN)

(72) Inventors: Quan Zhang, Wuhan (CN); Yanwei Shi, Wuhan (CN); Lan Yao, Wuhan (CN); Cheng Chen, Wuhan (CN); Boru Xie, Wuhan (CN); Jing Li, Wuhan (CN)

(21) Appl. No.: 18/148,805

(22) Filed: Dec. 30, 2022

(30) Foreign Application Priority Data
Nov. 16, 2022 (CN) 202211436530.1

(51) Int. Cl. H10B 80/00

(52) U.S. Cl. CPC H10B 80/00

(57) ABSTRACT

The present disclosure provides an example semiconductor devices and fabrication methods thereof, and memory systems. In one example, the semiconductor device includes: a first chip including a first type of transistor that is planar transistor and a second chip bound on the first chip in the first direction. The second chip includes a second type of transistor that is fin transistor. The semiconductor device and the fabrication method thereof, and the memory system provided in the present disclosure can mitigate the bulk effect between transistors in adjacent two chips. Other examples are disclosed.

### CROSS-REFERENCE TO RELATED APPLICATIONS

This application claims priority to and the benefit of Chinese Patent Application No. 202211436530.1, filed on Nov. 16, 2022, which is hereby incorporated by reference in its entirety.

### TECHNICAL FIELD

The present disclosure relates to the field of semiconductor technologies, and more particularly to a semiconductor device and a fabrication method thereof, and a memory system.

### BACKGROUND

Three-dimensional (3D) memory architecture can address the density limitation in planar memory cells. The 3D memory architecture includes a memory array and a peripheral circuit for facilitating operation of the memory array. The peripheral circuit is often bound on the memory array in form of chips. In related technical approaches, chips adjacent to the memory array would be affected by the bulk effect of chips apart from the memory array.

### BRIEF DESCRIPTION OF ACCOMPANYING DRAWINGS

In order to explain the technical solutions in some examples of the present disclosure more clearly, accompanying drawings required in describing examples will be described in brief below. It is obvious that the below described drawings are only some examples of the present disclosure and other drawings may be obtained by those skilled in the art according to these drawings without any creative work.

FIG. 1 is a sectional view a semiconductor device provided in some examples of the present disclosure.

FIG. 2 is a sectional view of another semiconductor device provided in some examples of the present disclosure.

FIG. 3 is an enlarged view of the second chip shown in FIG. 2.

FIG. 4 is a top view of the second chip shown in FIG. 3.

FIG. 5 is a perspective view of one of the second type of transistors shown in region V shown in FIG. 4.

FIG. 6 is a sectional view along VI-VI shown in FIG. 4.

FIG. 7 is a sectional view of yet another semiconductor device provided in some examples of the present disclosure.

FIG. 8 is a flowchart of a method of fabricating a semiconductor device provided in some examples of the present disclosure.

FIG. 9 is a flow chart of step S2 shown in FIG. 8.

FIG. 10 is a sectional view of an initial chip bound with the first chip provided in some examples of the present disclosure.

FIG. 11 is a sectional view after thinning the silicon crystal layer shown in FIG. 10.

FIG. 12 is a module diagram of a memory system provided in some examples of the present disclosure.

### DETAILED DESCRIPTION

The technical solutions in some examples of the present disclosure will be described clearly and fully below in connection with accompanying drawings in some examples of the present disclosure. Obviously, the described examples are only a part of examples of the present disclosure rather than all of them. Based on the examples of the present disclosure, all other examples obtained by those skilled in the art without any creative work fall within the scope of the present disclosure.

In the description of the present disclosure, it is to be understood that terms “on”, “under”, etc. refer to the azimuth or position relationship based on what is shown in figures, which are only for the purpose of facilitating describing the present disclosure and simplifying description rather than indicating or implying that the mentioned devices or elements must have certain azimuth, must be constructed and operated in certain azimuth, and therefore are not constructed as limiting the present disclosure. Furthermore, terms such as “first” and “second” are only for illustrative purpose rather than being understood to indicate or imply relative importance or implicitly indicating the number of the stated technical features. Therefore, a feature qualified by “first” or “second” may include explicitly or implicitly one or more instances of the feature. In the description of the present disclosure, “a plurality of” means two or more unless otherwise specified.

In the description of the present disclosure, it is understood that term “substrate” refers to a material on which subsequent material layer will be added. The substrate may be patterned itself. Materials added on top of the substrate may be patterned or may be kept intact.

In the description of the present disclosure, it is understood that the term “layer” refers to a material portion including a region with a thickness. A layer may extend across the entire lower structure or upper structure, or may have a range smaller than the range of the lower structure or upper structure. Furthermore, a layer may be a region of uniform or non-uniform continuous structure with a thickness smaller than that of a continuous structure. A layer can extend horizontally, vertically, and/or along a tapered surface. A layer can include multiple sub-layers. For example, an interconnect layer may include one or more conductors and contact sub-layers (wherein interconnect lines and/or via contacts are formed) and one or more dielectric sub-layers.

The present disclosure might repeat reference numerals and/or letters in different implementations, which is for the purpose of simplification and clarity rather than indicating relationships between the discussed implementations and/or arrangements.

In the present disclosure, in view of the technical problem that transistors of one chip in two bound chips might be affected by the bulk effect of transistors in another chip, a second chip including fin transistors is bound at one side of the first chip including planar transistors. The gate of a fin transistor has an enhanced controlling capability over the channel region. Given a constant controlling capability of gate over the channel region, as compared to the channel length of a planar transistor, the channel length of the fin transistor is shortened, which not only reduces the output impedance, but also reduces the threshold voltage and the bulk effect.

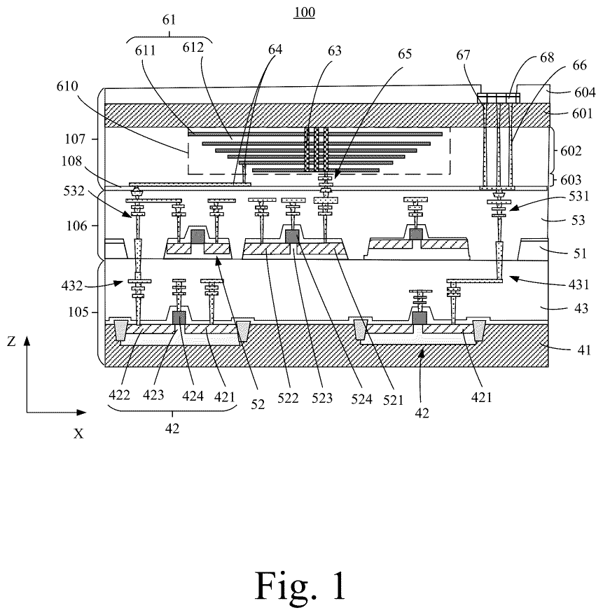

Referring to FIG. 1 that is a sectional view a semiconductor device 100 provided in some examples of the present disclosure. The semiconductor device 100 includes a first chip 105 and a second chip 106. In the first direction Z, the first chip 105 is bound at one side of the second chip 106. The second chip 106 is electrically connected with the first chip 105.

In some examples of the present disclosure, the semiconductor device 100 further includes a third chip 107 and the second chip 106 is bound with both the third chip 107 and the first chip 105. That is, the second chip 106 is positioned between the first chip 105 and the third chip 107. The second chip 106 and the first chip 105 are configured to control the third chip 107. The third chip 107 is electrically connected with the second chip 106 and the first chip 105 respectively.

Herein, the first chip 105 includes a substrate 41, at least one first type of transistor 42 and a first interconnect layer 43, in which the first type of transistor 42 is located on one side of the substrate 41, and the first interconnect layer 43 covers the substrate 41 and the first type of transistor 42.

The substrate 41 may include single crystalline silicon, poly-crystalline silicon, single-crystalline germanium, III-V compound semiconductor materials, II-VI compound semiconductor materials or other semiconductor materials.

Herein, the first type of transistor 42 is planar transistor. Specifically, the first type of transistor 42 includes a source region 421, a drain region 422, a channel region 423 and a gate 424, wherein the source region 421 and the drain region 422 are located in the substrate 41, the channel region 423 is located between the source region 421 and the drain region 422, and the projection of the gate 424 on the substrate 41 covers the channel region 423. The source region 421 and the drain region 422 of the first type of transistor 42 are formed in respective regions of the substrate 41 by method such as ion implantation. The source region 421 and the drain region 422 of the first type of transistor 42 extend from a surface of the substrate 41 proximate to the first interconnect layer 43 to the inside of the substrate 41.

In some examples of the present disclosure, the source region 421 and the second drain region 422 are arranged in the second direction X. In some other examples of the present disclosure, the source region 421 and the second source region 422 may also be arranged in the third direction Y. Herein, the third direction Y intersects with the second direction X and both are perpendicular to the first direction Z.

Herein, the first interconnect layer 43 includes first interconnect structures 431 and 432, an end of the first interconnect structure 431 is electrically connected with the source region 421 of the first type of transistor 42, and an end of the first interconnect structure 432 is electrically connected with the drain region 422 of the first type of transistor 42. In some examples of the present disclosure, the first interconnect structures 431 and 432 are electrically connected with two different first type of transistors 42 respectively.

In this example, the first type of transistor 42 may be a High-Voltage Complementary Metal Oxide Semiconductor (HV-CMOS). In other examples, the first type of transistor 42 is not limited to CMOS.

In the present example, the first type of transistor 42 is a high-voltage transistor. Specifically, the first type of transistor 42 has an operating voltage greater than 5 V.

Herein, the second chip 106 includes a substrate 51, at least one second transistor 52 and a second interconnect layer 53, in which the second transistor 52 is located on one side of the substrate 51, and the second interconnect layer 53 covers the substrate 51 and the second transistor 52.

The substrate 51 may include single crystalline silicon, poly-crystalline silicon, single-crystalline germanium, III-V compound semiconductor materials, II-VI compound semiconductor materials or other semiconductor materials.

Herein, the second transistors 52 are planar transistors. In particular, the second transistor 52 includes a source region 521, a drain region 522, a channel region 523 and a gate 524. The source region 521 and the drain region 522 of the second transistor 52 are formed in respective regions of the substrate 51 by ion doping method such as ion implantation and ion doping. The source region 521 and the drain region 522 of the second transistor 52 extend from a surface of the substrate 51 away from the first chip 105 to the inside of the substrate 51. The channel region 523 is located between the source region 521 and the drain region 522, and the projection of the gate 524 on the substrate 51 covers the channel region 523.

In some examples of the present disclosure, the gate 23 only faces a surface of the channel region 523 away from the first chip 105. Here, “face” means the projection of the gate 23 on the first chip 105 may completely cover the projection of the channel region 523 on the first chip 105.

Herein, the second interconnect layer 53 includes second interconnect structures 531 and 532, an end of the second interconnect structure 531 is electrically connected with the first interconnect structure 431, an end of the second interconnect structure 532 is electrically connected with the first interconnect structure 432, and the other end is electrically connected with the drain region 522 of the second transistor 52.

In some examples of the present disclosure, the second transistor 52 is a High-Voltage Complementary Metal Oxide Semiconductor (HV-CMOS). In other examples, the second transistor 52 is not limited to CMOS.

Herein, the second transistor 52 has an operating voltage smaller than that of the first type of transistor 42.

In some examples of the present disclosure, the second transistor 52 is a low-voltage (LV) transistor or a low-low-voltage (LLV) transistor. Specifically, when the second transistor 52 is a LV transistor, the operating voltage thereof is greater than 1.6 V and less than 3.3V. When the second transistor 52 is a LLV transistor, the operating voltage thereof is less than 1.6 V.

Herein, the second transistor 52 is adjacent to the first type of transistor 42.

Specifically, the third chip 107 is bonded with the second chip 106 via a bonding interface 104.

Herein, the third chip 107 includes a substrate 601, a semiconductor structure layer 602 and a third interconnect layer 603, the semiconductor structure 602 is located on the substrate 601, and the third interconnect layer 603 is located on the semiconductor structure 602.

In some examples of the present disclosure, the semiconductor structure 602 includes a memory structure 610 that includes a plurality of memory strings 63 and a stack 61, in which the memory strings 63 are embedded in the stack 61 in the first direction Z. The memory structure 610 is electrically connected with the first chip 105 and the second chip 106 to implement function support of the first chip 105 and the second chip 106 for the memory structure 610, such as reading, writing and erasing data in the memory cells.

The substrate 601 may include single crystalline silicon, poly-crystalline silicon, single-crystalline germanium, III-V compound semiconductor materials, II-VI compound semiconductor materials or other semiconductor materials.

Specifically, the stack 61 includes a plurality of electrode layers 611 and a plurality of interlayer insulating layers 612 disposed one over another alternatively. The memory strings 63 penetrate the plurality of electrode layers 611 and the plurality of interlayer insulating layers 612. Herein, materials for electrode layers 611, interlayer insulating layers 612 and memory strings 63 may be selected from materials commonly used to form electrode layers, insulating layers and memory strings in memory structures in the 3D memory field, and the structure of the memory string 63 may be selected from structures commonly used to form memory structures in 3D memory field.

In some examples of the present disclosure, electrode layers 611 and interlayer insulation layers 612 extend in the second direction X respectively. In some other examples of the present disclosure, electrode layers 611 and interlayer insulation layers 612 may also extend in the third direction Y respectively.

The third interconnect layer 603 includes third interconnect structures 64, 65 and 66. An end of the third interconnect structure 64 is electrically connected with one electrode layer 611, and the other end is electrically connected with an end of the second interconnect structure 532 away from the first chip 105. An end of the third interconnect structure 65 is electrically connected with one memory string 63, and the other end is electrically connected with one second transistor 52. Particularly, the other end of the third interconnect structure 65 is electrically connected with the source region 521 of one second transistor 52. An end of the third interconnect structure 66 penetrates the second chip 106 and is electrically connected with one first interconnect structure 432.

The third chip 107 further includes at least one contact structure 67 embedded in the substrate 601. An end of the third interconnect structure 66 away from the second interconnect structure 531 is electrically connected with the contact structure 67.

The third chip 107 further includes a fourth interconnect layer 604 and an external terminal 68 located at a side of the substrate 601 away from the second chip 106. The fourth interconnect layer 604 covers at least a part of the external terminal 68, another part of the external terminal 68 is exposed from the fourth interconnect layer 604. The external terminal 68 is configured to connect the memory structure 610 to the external circuit.

In this example, the second transistor 52 of the second chip 106 and the first type of transistor 42 of the first chip 105 have a small distance therebetween that is typically 100-500 nm. The second transistor 52 in the second chip 106 is affected by the bulk effect brought about by operation of the first type of transistor 42 (with high voltage).

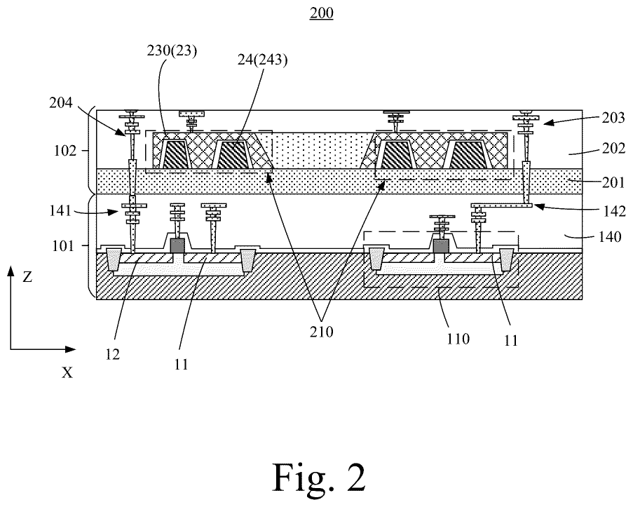

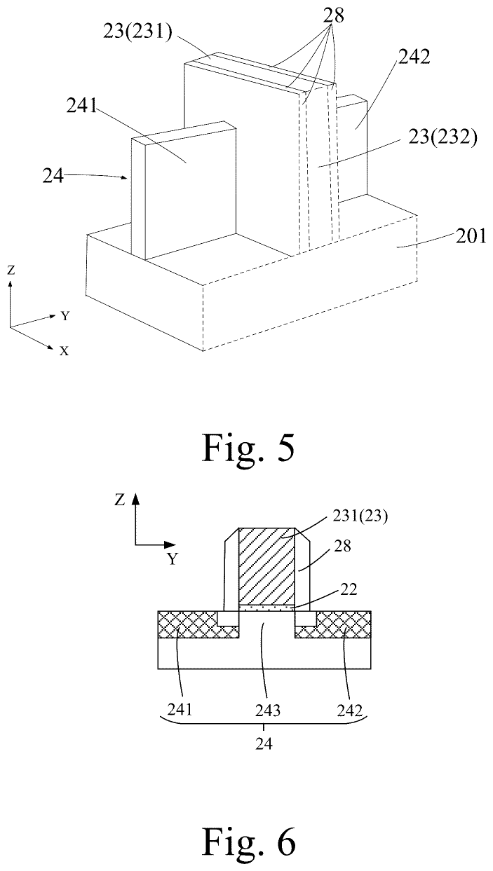

Referring to FIG. 2, some examples of the present disclosure further provides a semiconductor device 200 capable of mitigating bulk effect impact. The semiconductor device 200 has a structure similar to that of the semiconductor device 100 except that the structure of the transistor in the second chip 102 that is adjacent to the first chip 101 in the semiconductor device 200 is different from the structure of the transistor in the second chip 106 that is adjacent to the first chip 105 in the semiconductor device 100 and the semiconductor device 200 does not include the third chip. The structure of the semiconductor device 200 will be described in detail below with reference to FIGS. 2-6.

Specifically, referring to FIG. 2, the semiconductor device 200 includes a first chip 101 and a second chip 102. The first chip 101 includes at least a first type of transistor 110 that is a planar transistor. The second chip 102 is bound on the first chip 101 in the first direction Z. The second chip 102 includes at least a second type of transistor 210 that is a fin transistor.

In the semiconductor device 200, the second chip 102 including fin transistors is disposed on a side of the first chip 101 that has planar transistors and the gate of a fin transistor may cover the top face and side faces of the channel region of the fin transistor. The gate of a fin transistor has an enhanced controlling capability over the channel region. Given a constant controlling capability of the gate of fin transistor over the channel region of the fin transistor, as compared to the channel length of a planar transistor, the channel length of the fin transistor is shortened, which not only reduces the output impedance, but also reduces the threshold voltage and the bulk effect. In addition, as compared to the planar transistor, the gate in a fin transistor controls increased area of the channel with an enhanced gate control capability, thereby effectively mitigating the short channel effect in planar transistors, drastically improving circuit control and reducing leakage current, and also shortening gate length of transistors (namely the distance between source and drain). Due to the characteristic, the fin transistor needs not high doped channel, thereby effectively mitigating impurity ion scattering effect and increasing the carrier mobility of the channel.

In some examples of the present disclosure, the operating voltage of the first type of transistor 110 is higher than that of the second type of transistor 210. However, when a high voltage device (the first type of transistor 110) is adjacent to a low-voltage transistor (the second type of transistor 210), the second type of transistor 210 being a fin transistor can further mitigate the bulk effect caused by the high voltage device.

In some examples of the present disclosure, the first type of transistor 110 of the first chip 101 has the same structure as that of the first type of transistor 42 of the first chip 105 of the semiconductor device 100. The source region 11 and the drain region 12 of the first type of transistor 110 of the first chip 101 are arranged in the second direction X. In some other examples of the present disclosure, the source region 11 and the drain region 12 of the first type of transistor 110 of the first chip 101 may also be distributed in the third direction Y.

Optionally, the second type of transistor 210 is a low-voltage transistor or a low-low-voltage transistor. Specifically, when the second type of transistor 210 is a low-voltage (LV) transistor, the operating voltage thereof is greater than 1.6 V and less than 3.3V. When the second type of transistor 210 is a low-low-voltage (LLV) transistor, the operating voltage thereof is less than 1.6 V.

In some examples of the present disclosure, the second type of transistor 210 is a fin field-effect transistor (FinFET).

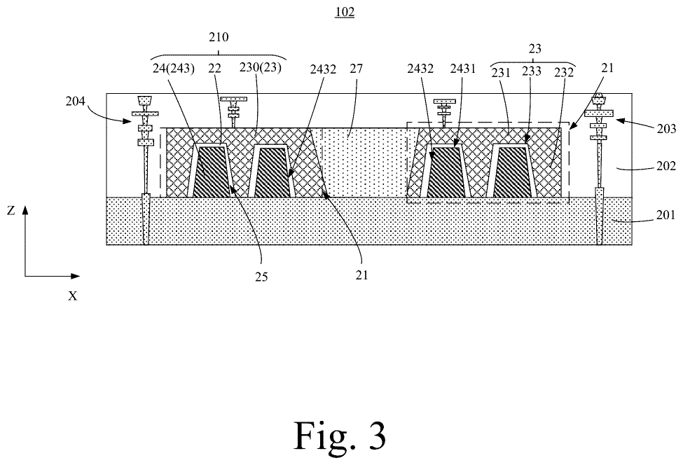

Specifically, referring to FIGS. 2-3, the second chip 102 includes at least a fin 24 and a gate layer 230 located on a side of the at least one fin 24 away from the first chip 101. Herein, each fin 24 extends in the second direction X.

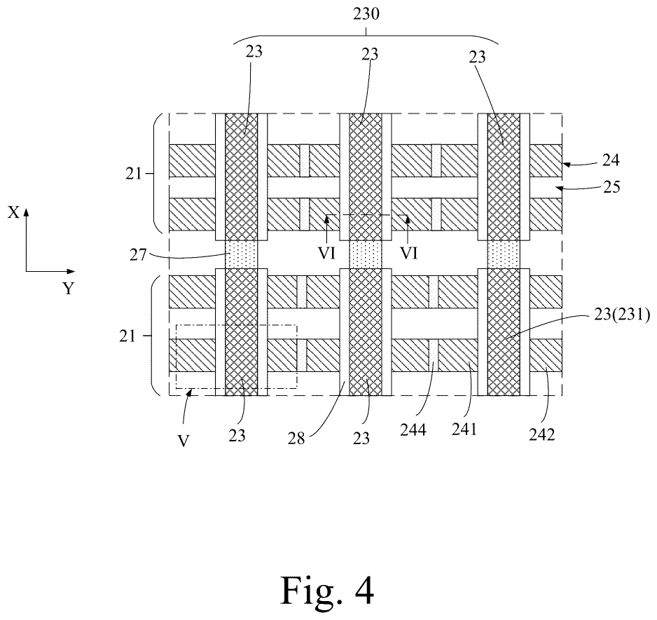

Referring to FIGS. 3-4, each fin 24 includes at least a source region 241, at least a channel region 243 and at least a drain region 242 distributed in sequence in the second direction X. The gate layer 230 includes at least one gate 23 each extends in the third direction Y and spans at least one fin 24 in the third direction Y. The projection of each gate 23 on the first chip 101 covers the projection of the at least one channel region 243 corresponding to it on the first chip 101. Herein, one second type of transistor 210 includes a channel region 243, a source region 241 and a drain region 242 on one fin 24 and partial gate 23 corresponding to the channel region 243.

Herein, the second type of transistor structure 21 includes a plurality of second type of transistors 210 sharing a gate 23.

Specifically, referring again to FIG. 3, the channel region 243 of each fin 24 includes a top face 2431 away from the first chip 101 and two side faces 2432 connected respectively with the top face on two sides of the top face 2431 in the third direction Y. Each gate 23 covers top face 2431 and side faces 2432 of the channel region 243 corresponding to it respectively.

In some examples of the present disclosure, the number of fins 24 is plurality. The plurality of fins 24 are distributed with spacings and there is a first spacer groove 25 between adjacent two fins 24. The projection of each gate 23 on the first chip 101 further covers the projection of the first spacer groove 25 between the plurality of fins 24 on the first chip 101. In this example, the first spacer groove 25 between adjacent fins 24 penetrates the fins.

Herein, fins 24 may be formed by methods such as wet etch and dry etch.

Herein, the thickness of fin 24 in the first direction Z is 24.5 angstroms to 69.0 angstroms.

In some examples of the present disclosure, each fin 24 includes three source regions 241, three drain regions 242 and three channel regions 243 with one source region 241, one drain region 242 and one channel region 243 as a group in which the channel region 243 is located between the source region 241 and the drain region 242. The source region 241 and the drain region 242 in adjacent two groups are spaced apart by a second spacer 244. Herein, the spacer 244 is configured to isolate adjacent source region 241 and drain region 242 and includes insulating material. Herein, the insulating material may include at least one of silicon oxide, silicon oxynitride, ethoxy silane, low temperature oxide, high temperature oxide and silicon nitride, to which the present disclosure is not limited.

Specifically, referring to FIGS. 3-6, each gate 23 includes a body 231 and a plurality of branches 232 fixed on the body 231. The body 231 extends in the third direction Y. The plurality of branches 232 extend in the first direction Z from the body 231 towards the first chip 101 respectively. Herein, the plurality of branches 232 are located between two adjacent fins 24 respectively. Specifically, the plurality of branches 232 are contained in the first spacer grooves 25 between two adjacent fins 24 respectively and the plurality of fins 24 are contained in the second spacer grooves 233 between two adjacent branches 232 respectively.

Herein, the body 231 of the gate 23 of the second type of transistor 210 covers the top face 2431 of the channel region 243 corresponding to it on the fin 24, adjacent two branches 232 of the gate 23 of the second type of transistor 210 cover respectively the two sides 2432 of the channel region 243 corresponding thereto, and the control capability of the gate 23 of the second type of transistor 210 over the channel region 243 of the second type of transistor 210 is enhanced. Given a constant control capability of the gate over the channel region, the channel length of the second type of transistor 210 is shortened, which not only reduces the output impedance, but also lowers the threshold voltage and mitigates the bulk effect. Herein, the channel length of the second type of transistor 210 refers to the length of the top face 2431 of the channel region 243 in the second direction X, that is, the distance between the source region 241 and the drain region 242 of the second type of transistor in the second direction X.

In some examples of the present disclosure, the number of gates 23 is plurality. The second chip 102 further includes at least one first spacer 27 located between the adjacent two gates 23 to isolate them. The spacer 27 includes insulating material. The insulating material may include at least one of silicon oxide, silicon oxynitride, ethoxy silane, low temperature oxide, high temperature oxide and silicon nitride, to which the present disclosure is not limited.

Specifically, referring again to FIGS. 3 and 6, each second type of transistor 210 further includes an oxidation layer 22 between the channel region 243 and the gate 23 of the respective second type of transistor 210 corresponding to it. The oxidation layer 22 is configured to isolate the gate 23 and the channel region 243.

Specifically, referring again to FIGS. 3 and 6, each second type of transistor 210 further includes sidewalls 28 formed on opposite sides of the gate 23 of each second type of transistor 210 in the second direction X and extending in the third direction Y. The sidewalls 28 function to prevent the gate 23 from contacting the source region 241 and the drain region 242, etc. Preferably, the sidewalls 28 include insulating material. The insulating material may include at least one of silicon oxide, silicon oxynitride, ethoxy silane, low temperature oxide, high temperature oxide and silicon nitride, to which the present disclosure is not limited.

Specifically, referring to FIG. 3 again, the second chip 102 further includes an insulating layer 201. The first chip 101 is bound on the insulating layer 201 and the second type of transistor 210 is located on a side of the insulating layer 201 away from the first chip 101. The insulating layer 201 includes insulating material. The insulating material may include at least one of silicon oxide, silicon oxynitride, ethoxy silane, low temperature oxide, high temperature oxide and silicon nitride etc. to which the present disclosure is not limited.

Specifically, the insulating layer 201 is formed on the first interconnect layer 140 of the first chip 101.

In some examples of the present disclosure, the thickness of the insulating layer 201 is 1 μm-10 μm. Further, the thickness of the insulating layer 201 is 3 μm-5 μm.

In some examples of the present disclosure, one ends of the plurality of branches 232 of the gate 23 away from the body 231 contact the insulating layer 201.

In other examples of the present disclosure, one ends of the plurality of branches 232 of the gate 23 away from the body 231 may also not contact the insulating layer 201. At this time, the first spacer groove 25 between adjacent fins 24 do not penetrates the fins.

Herein, providing the insulating layer 201 between the second type of transistor 210 and the first chip 101 may increase the distance between the first type of transistor 110 and the second type of transistor 210 and further reduce the bulk effect of the first type of transistor 110 on the second type of transistor 210. Herein, the insulating layer 201 with a thickness greater than 10 μm will increase the difficulty of interconnecting chips and increase the process costs. The insulating layer 201 with a thickness less than 1 μm will have no obvious effect of reducing the bulk effect on the second chip 102.

Referring again to FIG. 2, the second chip 102 further includes a fifth interconnect layer 202 covering the insulating layer 201 and the gate layer 230, which includes the fourth interconnect structures 203 and 204.

Herein, the fourth interconnect structures 203 and 204 function to connect external electronic devices, etc.

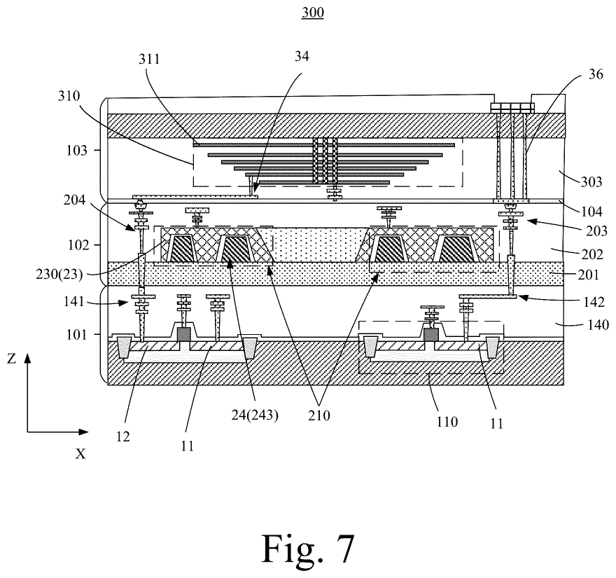

Referring to FIG. 7, some examples of the present disclosure further provides a semiconductor device 300 that is different from the semiconductor device 200 in that the semiconductor device 300 further includes a third chip 103 with a structure same as that of the semiconductor device 100. The fourth interconnect structure 203 is electrically connected with the first interconnect structure 142 of the first chip 101 and the third interconnect structure 36 of the third chip 103 respectively. The fourth interconnect structure 204 of the second chip 102 is electrically connected with the first interconnect structure 141 of the first chip 101 and the third interconnect structure 34 of the third chip 103 respectively. The bonding interface 104 is located between the fifth interconnect layer 202 and the third interconnect layer 303 of the third chip 103. The bonding interface 104 is configured to bond the second chip 102 and the third chip 103.

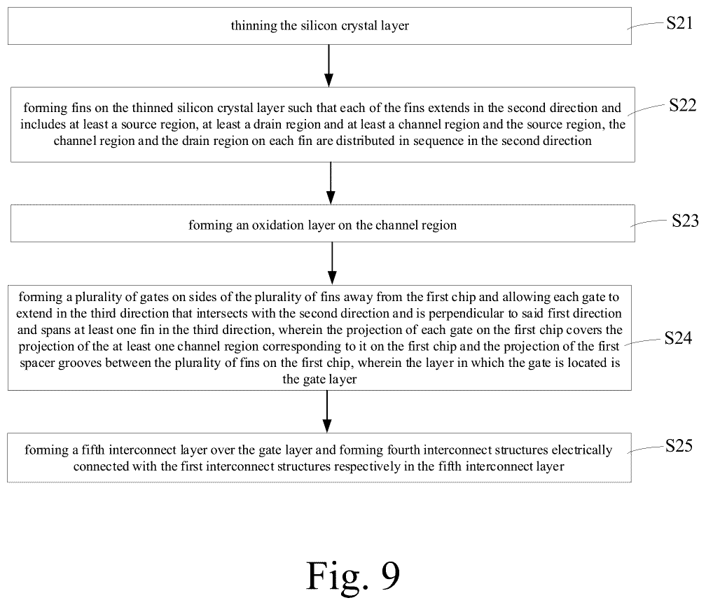

Referring to FIGS. 3 and 8-11, the present disclosure further provides a fabrication method of a semiconductor device 200, comprising:

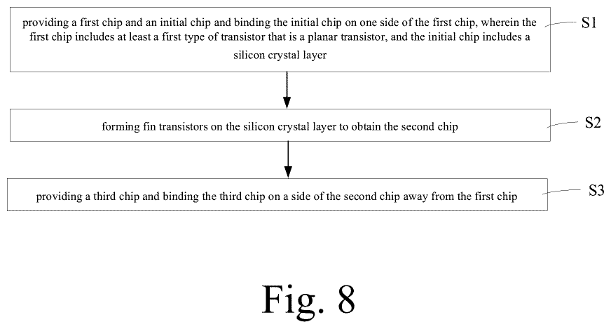

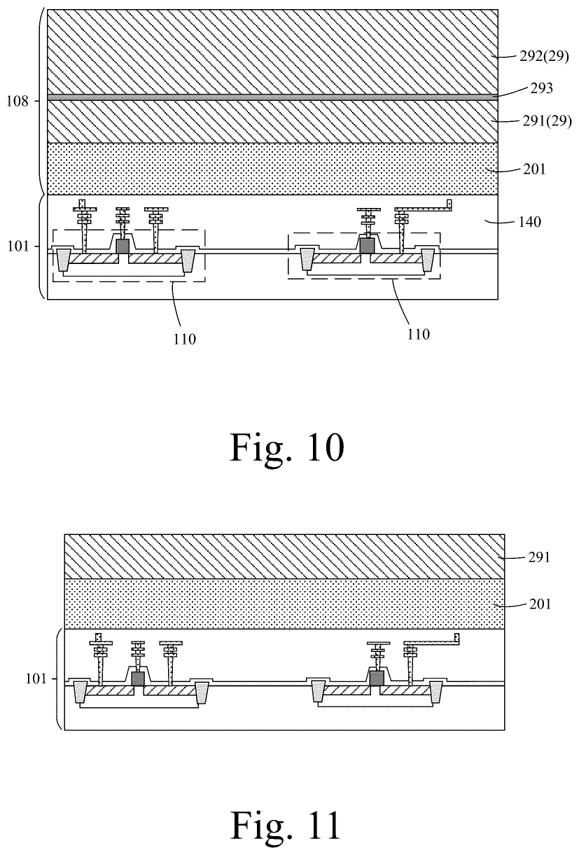

step S1: referring to FIGS. 8 and 10, providing a first chip 101 and an initial chip 108 and binding the initial chip 108 on one side of the first chip 101, wherein the first chip 101 includes at least a first type of transistor 110 that is a planar transistor, and the initial chip 108 includes a silicon crystal layer 29.

In some examples of the present disclosure, since the fin transistor is fabricated with the silicon-on-insulator (SOI) technology, the initial chip 108 further includes an insulating layer 201 located between the silicon crystal layer 29 and the first chip 101.

In some examples of the present disclosure, the operating voltage of the first type of transistor 110 is higher than that of the second type of transistor 210. However, when a high voltage device (the first type of transistor 110) is adjacent to a low-voltage transistor (the second type of transistor 210), the second type of transistor 210 being a fin transistor can further mitigate the bulk effect caused by the high voltage device.

The initial chip 108 further includes an insulating layer 201 between the second type of transistor 210 and the first chip 101. The insulating layer 201 may increase the distance between the first type of transistor 110 and the second type of transistor 210 and further reduce the bulk effect of the first type of transistor 110 of the first chip 101 on the second type of transistor 210 of the second chip 102.

Specifically, the insulating layer 201 is formed on the first interconnect layer 140 of the first chip 101.

In some examples of the present disclosure, the thickness of the insulating layer 201 is 1 μm-10 μm. Further, the thickness of the insulating layer 201 is 3 μm-5 μm.

Herein, the insulating layer 201 with a thickness greater than 10 μm will increase the difficulty of interconnecting chips and increase the process costs. The insulating layer 201 with a thickness less than 1 μm will have no obvious effect of reducing the bulk effect on the second chip 102.

Step S2: referring to FIGS. 8, 10, 11 and 3, forming fin transistors on the silicon crystal layer 29 to obtain the second chip 102.

In step S2, a semiconductor device 200 is further obtained that includes a first chip 101 and a second chip 102.

Herein, the fin transistor is a second type of transistor 210.

Specifically, referring to FIGS. 9, 11 and 3, step S2 includes:

step S21: thinning the silicon crystal layer 29 to obtain a thinned silicon crystal layer 291. Specifically, referring to FIGS. 10-11, step S21 includes: first referring to FIG. 10, injecting hydrogen in the silicon crystal layer 29 to form a silicon-hydrogen structure layer 293 that divides the silicon crystal layer 29 into two parts (the thinned silicon crystal layer 291 and the silicon crystal layer 292 to be removed) in the silicon crystal layer 29; next referring to FIG. 11, heating the first chip 101 and the initial chip 108 to remove the silicon-hydrogen structure layer 293 and the silicon crystal layer 292 to be removed on the silicon-hydrogen structure layer 293 to obtain the thinned silicon crystal layer 291.

Step S22: forming fins 24 on the thinned silicon crystal layer 291 and allowing each fin 24 to extend in the second direction x and include at least a source region 241, at least a drain region 242 and at least a channel region 243, wherein the source region 241, the channel region 243 and the drain region 242 on each fin 24 are distributed in sequence in the second direction X.

In step S22, it is possible to form a plurality of spacer grooves 25 on the thinned silicon crystal layer 291 by such as dry etch or wet etch processes to obtain a plurality of fins 24, and form the source regions 241, the drain regions 242 and the channel regions 243 in respective regions of the fins 24 by methods such as ion implantation. Herein, the thickness of fin 24 in the first direction Z is 24.5 angstroms to 69.0 angstroms.

Step S23: forming an oxidation layer 22 on the channel region 243.

Step S24: forming at least one gate 23 on one side of the fin 24 away from the first chip 101 and allowing each gate 23 to extends in the third direction Y that intersects with the second direction X and is perpendicular to the first direction Z and spans at least one fin 24 in the third direction Y, wherein the projection of each gate 23 on the first chip 101 covers the projection of the at least one channel region 243 corresponding to it on the first chip 101. Herein, the layer in which the gate 23 is located is the gate layer 230.

In step S24, the oxidation layer 22 is between the gates 23 and the fins 24. In step S24,

It is possible to form the gate layer 230 with any one of processes such as atomic layer deposition, physical vapor deposition or chemical vapor deposition, and then remove parts of the gate layer 230 that are not in the target region by processes such as etch to form gates 23.

After step S24, a step is further included: forming two sidewalls 28 extending in the third direction Y on opposite sides of the gate 23 of each second type of transistor 210 in the second direction X.

Specifically, referring again to FIG. 3, the channel region 243 of each fin 24 includes a top face 24 away from the first chip 101 and two side faces 2432 connected with the top face respectively on two sides of the top face 2431 in the third direction Y. Each gate 23 covers top face 2431 and side faces 2432 of the channel region 243 corresponding to it respectively. Each gate 23 includes a body 231 and a plurality of branches 232 fixed on the body 231. The body 231 extends in the third direction Y. The plurality of branches 232 extend in the first direction Z from the body 231 towards the first chip 101 respectively. Herein, the plurality of branches 232 are located between two adjacent fins 24 respectively. Specifically, the plurality of branches 232 are contained in the first spacer grooves 25 between two adjacent fins 24 respectively and the plurality of fins 24 are contained in the second spacer grooves 233 between two adjacent branches 232 respectively.

Herein, the body 231 of the gate 23 of the second type of transistor 210 covers the top face 2431 of the channel region 243 corresponding to it on the fin 24, adjacent two branches 232 of the gate 23 of the second type of transistor 210 cover the two sides 2432 of the channel region 243 corresponding to it, and the control capability of the gate 23 of the second type of transistor 210 over the channel region 243 of the second type of transistor 210 is enhanced. Given a constant control capability of the gate over the channel region, the channel length of the second type of transistor 210 is shortened, which not only reduces the output impedance, but also lowers the threshold voltage and mitigates the bulk effect. Herein, the channel length of the second type of transistor 210 refers to the length of the top face 2431 of the channel region 243 in the second direction X, that is, the distance between the source region 241 and the drain region 242 of the second type of transistor in the second direction X.

In some examples of the present disclosure, the number of gates 23 is plurality. The second chip 102 further includes at least one first spacer 27 located between the adjacent two gates 23 to isolate them.

One second type of transistor 210 includes a channel region 243, a source region 241 and a drain region 242 on one fin 24 and partial gate 23 corresponding to the channel region 243. One second type of transistor 210 further includes an oxidation layer 22 between the gate 23 and the channel region 243.

Step S25: forming a fifth interconnect layer 202 on the gate layer 230 and forming fourth interconnect structures 203 and 204 electrically connected with the first interconnect structures 142 and 141 respectively in the fifth interconnect layer 202.

Of course, in other examples of the present disclosure, the method for fabricating fin transistors is not limited to SOI technology, and may be other methods for fabricating fin transistors well known by those skilled in the art.

Referring to FIGS. 7-11, the present disclosure further provides a fabrication method of a semiconductor device 300, in addition to the above-described steps S1 and S2, further including:

step S3, referring to FIGS. 7, 3 and 2, providing a third chip 103 and binding the third chip 103 on a side of the second chip 102 away from the first chip 101 to obtain the semiconductor device 300.

In step S3, the third chip 103 is bound with the second chip 102 via a bonding interface 104. Specifically, the bonding interface 104 is located between the fifth interconnect layer 202 and the third interconnect layer 303.

Specifically, the third chip 103 includes a memory structure 310 and third interconnect structures 34 and 36. An end of the third interconnect structure 34 is electrically connected with the electrode layer 311 of the memory structure 310. The fourth interconnect structure 203 is electrically connected with the first interconnect structure 142 of the first chip 101 and the third interconnect structure 36 of the third chip 103 respectively. The fourth interconnect structure 204 of the second chip 102 is electrically connected with the first interconnect structure 141 of the first chip 101 and the third interconnect structure 34 of the third chip 103 respectively. The bonding interface 104 is located between the fifth interconnect layer 202 and the third interconnect layer 303 of the third chip 103.

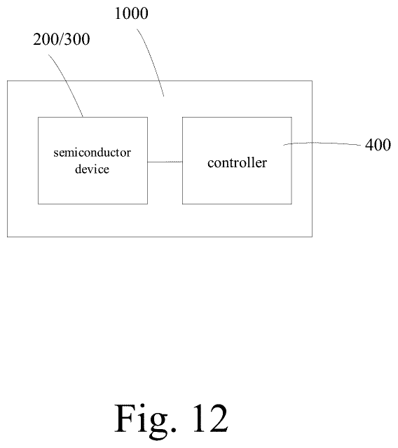

Referring to FIG. 12, the present disclosure further provides a memory system 1000 including one or more semiconductor devices 200 or 300 as described above and a controller 400 electrically connected with the semiconductor device 200 or 300 and configured to control the semiconductor device 200 or 300.

Herein, the memory system 1000 may be integrated into various storage devices such as being included in the same package (such as Universal Flash Storage (UFS)) or Embedded Multi Media Card (eMMC) package. That is, the memory system 1000 can be applied to and encapsulated in different types of electronic products such as a mobile phone, a desktop computer, a laptop computer, a tablet, a vehicle computer, a gaming console, a printer, a positioning device, a wearable electronic device, a smart sensor, a virtual reality (VR) device, an argument reality (AR) device, or any other suitable electronic devices having a memory therein.

In some other examples, the memory system 1000 may be integrated into a memory card.

Herein, the memory card includes any one of a PC card (PCMCIA), a Compact Flash (CF) card, a Smart Media (SM) card, a memory stick, a Multimedia Card (MMC), a Secure Digital Memory Card (SD) or a UFS.

In some other examples, the memory system 1000 may also be integrated into a solid state drive (SSD).

In some examples, the controller 400 is configured to operate in low duty cycle environment, such as SD cards, CF cards, Universal Serial Bus (USB) flash drives, or other media used in electronic devices such as personal calculators, digital cameras and mobile phones.

In some other examples, the controller 400 is configured to operate in high duty cycle environment SSDs or eMMCs that are used as data stores and enterprise memory arrays of the mobile devices such as smart phones, tablet computers and laptop computers.

In some examples, the controller 400 may be configured to manage data stored in the semiconductor device 200 or 300 and communicate with external equipment such as hosts. In some examples, the controller 400 can further be configured to control operations of the semiconductor device 200 or 300, such as read, erase, and program operations. In some examples, the controller 400 can also be configured to manage various functions with respect to the data stored or to be stored in the semiconductor device 200 or 300, including at least one of bad-block management, garbage collection, logical-to-physical address conversion, wear leveling, etc. In some examples, the controller 400 is further configured to process error correction codes with respect to data read from or written into the semiconductor device 200 or 300.

Of course, the controller 400 may further execute any other suitable functions such as formatting the semiconductor device 200 or 300. For example, the controller 400 may communicate with an external equipment such as a host via at least one of various interface protocols.

It is to be noted that the interface protocols include at least one of USB protocol, MMC protocol, peripheral component interconnection (PCI) protocol, PCI-express (PCI-E) protocol, advanced technology attachment (ATA) protocol, serial-ATA protocol, parallel-ATA protocol, small computer small interface (SCSI) protocol, enhanced small disk interface (ESDI) protocol, integrated drive electronics (IDE) protocol and Firewire protocol.

In the semiconductor device 200 and 300 provided in the present disclosure, the second chip 102 including fin transistors is disposed on a side of the first chip 101 that has planar transistors and the gate of a fin transistor may cover the top face and side faces of the channel region of the fin transistor. The gate of a fin transistor has an enhanced controlling capability over the channel region. Given a constant controlling capability of the gate of fin transistor over the channel region of the fin transistor, as compared to the channel length of a planar transistor, the channel length of the fin transistor is shortened, which not only reduces the output impedance, but also reduces the threshold voltage and the bulk effect. In addition, as compared to the planar transistor, the gate in a fin transistor controls increased area of the channel with an enhanced gate control capability, thereby effectively mitigating the short channel effect in planar transistors, drastically improving circuit control and reducing leakage current, and also shortening gate length of transistors (namely the distance between source and drain). Due to this characteristic, the fin transistor needs not high doped channel, thereby effectively mitigating impurity ion scattering effect and increasing the carrier mobility of the channel. On the other hand, thanks to the thickness design of the insulating layer, it is also possible to further isolate relatively high operating voltage devices and mitigate the bulk effect caused by the high voltage devices.

In view of this, the present disclosure provides a semiconductor device and a fabrication method thereof and a memory system that can mitigate bulk effect between transistors in adjacent two chips.

In order to address the above-described problem, the technical solution provided in the present disclosure is as follows.

In the first aspect, the present disclosure provides a semiconductor device, including:
a first chip including at least a first type of transistor that is planar transistor;
and a second chip bound on the first chip in a first direction, wherein the second chip comprises at least a second type of transistor that is fin transistor.

In some examples, an operating voltage of the first type of transistors is higher than that of the second type of transistors.

In some examples, the second chip comprises at least one fin and a gate layer;
each of the fins extends in a second direction and comprises at least a source region, at least a channel region and at least a drain region; the source region, the channel region and the drain region on each of the fins are distributed in sequence in the second direction; and
the gate layer is located at a side of the fin away from the first chip; the gate layer comprises at least a gate, and each of the gates extends in a third direction that intersects with the second direction and is perpendicular to the first direction and spans at least one of the fins; a projection of each of the gates on the first chip covers a projection of at least one of the channel regions corresponding to it on the first chip;
wherein one of the second type of transistors comprises the channel region, the source region and the drain region on one of the fins and a part of the gate corresponding to the channel region.

In some examples, the channel region of each of the fins comprises a top face away from the first chip and two side faces connected with the top face respectively and located on two sides of the top face in the third direction; each of the gates covers the top face and the two side faces of the one channel region corresponding to it, respectively.

In some examples, the source regions and the drain regions of the first type of transistors are arranged in the second direction.

In some examples, the source regions and the drain regions of the first type of transistors are arranged in the third direction.

In some examples, the second chip comprises a plurality of the fins distributed with spacings; each of the gates comprises a body and a plurality of branches fixed on the body; the body extends in an extending direction of each of the gates; the plurality of branches extend respectively towards the first chip in the first direction from the body;
wherein the plurality of branches are located between two adjacent ones of the fins respectively.

In some examples, each of the second type of transistors further comprises an oxidation layer located between the channel region and the gate of each of the second type of transistors corresponding to it.

In some examples, each of the second type of transistors further comprises sidewalls formed on opposite sides of the gate of each of the second type of transistors in the second direction and extending in the third direction Y.

In some examples, the second type of transistor structure comprises a plurality of the second type of transistors sharing one of the gates.

In some examples, the second chip further comprises at least one first spacer located between adjacent two of the gates.

In some examples, the semiconductor device further comprises a third chip bound on a surface of the second chip away from the first chip; one of the second type of transistors is connected with the third chip, the first type of transistors are connected with the second type of transistors;
wherein the third chip comprises a memory structure.

In some examples, the second chip further comprises an insulating layer on which the first chip is bound, and the second type of transistors are located on a side of the insulating layer away from the first chip.

In some examples, a thickness of the insulating layer is 1 μm-10 μm.

In some examples, a thickness of the fin 24 in the first direction is 24.5 angstroms to 69.0 angstroms.

In some examples, a thickness of the fin in the first direction is 24.5 angstroms to 69.0 angstroms.

The second aspect of the present disclosure further provides a method of fabricating a semiconductor device, including:
providing a first chip and an initial chip and binding the initial chip on a side of the first chip; wherein the first chip comprises at least a first type of transistor, the initial chip comprises a silicon crystal layer; and
forming the second type of transistor that is fin transistor on the silicon crystal layer to obtain the second chip.

In some examples, the step of forming the silicon crystal layer into fin transistors to obtain the second chip comprises:
forming fins on the silicon crystal layer such that each of the fins extends in a second direction and comprises at least a source region, at least a drain region and at least a channel region, the source region, the channel region and the drain region on each of the fins are distributed in sequence in the second direction; and
forming a plurality of gates on sides of the plurality of fins away from the first chip such that each of the gates extends in a third direction that intersects with the second direction and is perpendicular to the first direction and spans at least one of the fins, a projection of each of the gates on the first chip covers a projection of at least one of the channel regions corresponding to it on the first chip; wherein one of the second type of transistors comprises the channel region, the source region and the drain region on one of the fins and a part of the gate corresponding to the channel region.

In some examples, before the step of forming fins on the silicon crystal layer, further comprising a step of: thinning the silicon crystal layer;

before the step of forming at least a gate on a side of the fin away from the first chip, further comprising a step of: forming an oxidation layer on the channel region; wherein the oxidation layer is located between the gate and the channel region;

after the step of forming the second type of transistor that is fin transistor on the silicon crystal layer to obtain the second chip, further comprising a step of: providing a third chip and binding the third chip on a side of the second chip away from the first chip.

In some examples, the step of thinning the silicon crystal layer comprises: the initial chip further comprises an insulating layer located between the silicon crystal layer and the first chip;
injecting hydrogen into the silicon crystal layer to form a silicon-hydrogen structure layer that divides the silicon crystal layer into two parts in the silicon crystal layer; and
heating the first chip and the initial chip to remove the silicon-hydrogen structure layer and a part of the silicon crystal layer on the silicon-hydrogen structure layer.

The third aspect of the present disclosure further provides a memory system, comprising:
one or more semiconductor devices as described above; and
a controller connected with the semiconductor device and configured to control the semiconductor device.

In the semiconductor device and the fabrication method thereof provided in the present disclosure, the second chip including fin transistors is bound on a side of the first chip including planar transistors. The gate of a fin transistor has an enhanced controlling capability over the channel region. Given a constant controlling capability of gate over the channel region, as compared to the channel length of a planar transistor, the channel length of the fin transistor is shortened, which not only reduces the output impedance, but also reduces the threshold voltage and the bulk effect.

In summary, the present disclosure has been disclosed above with reference to preferred examples, however the preferred examples above are not used to limit the present disclosure. On the contrary, variations and modifications may be made by those of ordinary skills in the art without departing from the spirit and scope of the present disclosure, which has a scope only defined by the claims.

What is claimed is:

1. A semiconductor device comprising:
a first chip including a first type of transistor that is planar transistor; and
a second chip bound on the first chip in a first direction Z, wherein the second chip includes a second type of transistor that is a fin transistor.

2. The semiconductor device of claim 1, wherein an operating voltage of the first type of transistor is higher than that of the second type of transistor.

3. The semiconductor device of claim 1, wherein the second chip comprises a fin and a gate layer;
each of the fins extends in a second direction and comprises a source region, a channel region and a drain region; the source region, the channel region and the drain region on each of the fins are distributed in sequence in the second direction; and
the gate layer is located at a side of the fin away from the first chip; the gate layer comprises a gate, and each of the gates extends in a third direction that intersects with the second direction and is perpendicular to the first direction and spans one of the fins; a projection of each of the gates on the first chip covers a projection of one of the channel regions corresponding to it on the first chip;
wherein one of the second type of transistors comprises the channel region, the source region and the drain region on one of the fins and a part of the gate corresponding to the channel region.

4. The semiconductor device of claim 3, wherein the channel region of each of the fins comprises a top face away from the first chip and two side faces connected with the top face respectively and located on two sides of the top face in the third direction; each of the gates covers the top face and the side faces of the channel region corresponding to it.

5. The semiconductor device of claim 3, wherein the source region and the drain region of the first type of transistor are arranged in the second direction.

6. The semiconductor device of claim 3, wherein the source region and the drain region of the first type of transistor are arranged in the third direction.

7. The semiconductor device of claim 3, wherein the second chip comprises a plurality of the fins distributed with spacings; each of the gates comprises a body and a plurality of branches fixed on the body; the body extends in the third direction; the plurality of branches extend towards the first chip in the first direction from the body respectively;
wherein the plurality of branches are located between two adjacent ones of the fins respectively.

8. The semiconductor device of claim 3, wherein each of the second type of transistors further comprises an oxidation layer located between the channel region and the gate of each of the second type of transistors corresponding to it.

9. The semiconductor device of claim 3, wherein each of the second type of transistors further comprises sidewalls formed on opposite sides of the gate of each of the second type of transistors in the second direction and extending in the third direction.

10. The semiconductor device of claim 5, wherein the second type of transistor comprises a plurality of the second type of transistors sharing one of the gates.

11. The semiconductor device of claim 3, wherein the second chip further comprises a first spacer located between adjacent two of the gates.

12. The semiconductor device of claim 1, wherein the semiconductor device further comprises a third chip bound on a surface of the second chip away from the first chip; one of the second type of transistors and of the first type of transistors are connected with the third chip respectively; wherein the third chip comprises a memory structure.

13. The semiconductor device of claim 1, wherein the second chip further comprises an insulating layer on which the first chip is bound, and the second type of transistor is located on a side of the insulating layer away from the first chip.

14. The semiconductor device of claim 13, wherein a thickness of the insulating layer is 1 μm-10 μm.

15. The semiconductor device of claim 3, wherein a thickness of the fin in the first direction is 24.5 angstroms to 69.0 angstroms.

16. A fabrication method of a semiconductor device, the method comprising:
providing a first chip and an initial chip and binding the initial chip on a side of the first chip in a first direction Z; wherein the first chip comprises a first type of transistor, the initial chip comprises a silicon crystal layer; and
forming a second type of transistor that is a fin transistor on the silicon crystal layer to obtain a second chip.

17. The fabrication method of the semiconductor device of claim 16, wherein the step of forming the second type of transistor that is fin transistor on the silicon crystal layer to obtain the second chip comprises:
forming fins on the silicon crystal layer such that each of the fins extends in a second direction and comprises a source region, a drain region and a channel region, the source region, the channel region and the drain region on each of the fins are distributed in sequence in the second direction; and
forming a gate on a side of the fin away from the first chip such that each of the gates extends in a third direction that intersects with the second direction and is perpendicular to the first direction and spans one of the fins, a projection of each of the gates on the first chip covers a projection of one of the channel regions corresponding to it on the first chip; wherein one of the second type of transistors comprises the channel region, the source region and the drain region on one of the fins and a part of the gate corresponding to the channel region.

18. The fabrication method of the semiconductor device of claim 17, wherein before the step of forming fins on the silicon crystal layer, further comprising a step of: thinning the silicon crystal layer to obtain a thinned silicon crystal layer;
before the step of forming a gate on the side of the fin away from the first chip, further comprising a step of: forming an oxidation layer on the channel region; wherein the oxidation layer is located between the gate and the channel region;
after the step of forming the second type of transistor that is fin transistor on the silicon crystal layer to obtain the second chip, further comprising a step of: providing a third chip and binding the third chip on a side of the second chip away from the first chip.

19. The fabrication method of the semiconductor device of claim 18, wherein the initial chip further comprises an insulating layer located between the silicon crystal layer and the first chip, and wherein the step of thinning the silicon crystal layer comprises:
injecting hydrogen into the silicon crystal layer to form a silicon-hydrogen structure layer that divides the silicon crystal layer into two parts in the silicon crystal layer; and
heating the first chip and the initial chip to remove the silicon-hydrogen structure layer and a part of the silicon crystal layer on the silicon-hydrogen structure layer, obtaining a thinned silicon crystal layer.

20. A memory system, comprising:
a semiconductor device comprising:
a first chip including a first type of transistor that is planar transistor; and
a second chip bound on the first chip in a first direction Z, wherein the second chip includes a second type of transistor that is a fin transistor; and
a controller connected with the semiconductor device and configured to control the semiconductor device.
